(19) United States
(12) Patent Application Publication
(10) Pub. No.: US 2026/0020172 A1
(43) Pub. Date: Jan. 15, 2026

(54) SUPPORT DEVICE AND FOLDABLE DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Jun ZHANG, Beijing (CN); Wei QING, Beijing (CN); Zhihui WANG, Beijing (CN); Chuankun YOU, Beijing (CN); Fengping WU, Beijing (CN)

(21) Appl. No.: 18/881,786

(22) PCT Filed: May 20, 2024
(86) PCT No.: PCT/CN2024/094182

§ 371 Date: Jan. 7, 2025

(30) Foreign Application Priority Data
May 29, 2023 (CN) 202310620176.6

(51) Int. Cl. H05K 5/02; F16C 11/04

(52) U.S. Cl. CPC H05K 5/0226; F16C 11/04

(57) ABSTRACT

Provided is a support device. The support device includes: a first support plate, a second support plate, and a hinge. The hinge is configured to allow a bendable portion of a flexible display module to be folded or unfolded. The hinge at least includes a flip assembly, the flip assembly including: a first flip plate, a fixing member, a connection wrap member, a slide member, a first elastic member, and a second flip plate. The first elastic member is disposed between the fixing member and the slide member, and a first compression amount of the first elastic member in a case where the support device is not connected to the flexible display module is less than a second compression amount of the first elastic member in a case where the support device is connected to the flexible display module.

### CROSS-REFERENCE TO RELATED APPLICATIONS

This application is a U.S. national stage of international application No. PCT/CN2024/094182, filed on May 20, 2024, which claims priority to Chinese Patent Application No. 202310620176.6, filed on May 29, 2023, entitled “SUPPORTING DEVICE AND FOLDING DISPLAY DEVICE,” the disclosures of which are herein incorporated by reference in their entireties.

### TECHNICAL FIELD

The present disclosure relates to the field of display technologies, and in particular, relates to a support device and a foldable display device.

### BACKGROUND

With the development of science and technology, flexible display panels are widely used in foldable display devices due to their good bending properties.

### SUMMARY

The present disclosure provides a support device and a foldable display device. The technical solutions are as follows.

According to an aspect, a support device is provided. The support device is configured to be connected to a flexible display module to support the flexible display module, the flexible display module including a bendable portion and a first unbendable portion and a second unbendable portion disposed on two sides of the bendable portion; wherein the support device includes: a first support plate, configured to support the first unbendable portion; a second support plate, configured to support the second unbendable portion; and a hinge, configured to allow the bendable portion to be folded or unfolded; wherein the hinge at least includes a flip assembly, the flip assembly including:
a first flip plate, fixedly connected to the first support plate;
a fixing member, rotatably connected to the first flip plate;
a connection wrap member, wrapping the fixing member and fixedly connected to the fixing member;
a slide member, wrapped by the connection wrap member and slidably connected to the fixing member;
a first elastic member, disposed between the fixing member and the slide member with one end of the first elastic member being connected to the fixing member and another end of the first elastic member being connected to the slide member; and
a second flip plate, fixedly connected to the second support plate and rotatably connected to the slide member;
wherein the first elastic member is in a compressed state, and a first compression amount of the first elastic member in a case where the support device is not connected to the flexible display module is less than a second compression amount of the first elastic member in a case where the support device is connected to the flexible display module.

In some embodiments, in the case that the support device is not connected to the flexible display module, the slide member is in abutment against an inner wall of the connection wrap member under an elastic force of the first elastic member; or
in the case that the support device is connected to the flexible display module, a gap is present between the slide member and an inner wall of the connection wrap member.

In some embodiments, in the case that the support device is not connected to the flexible display module and the support device is in an unfolded state, a first gap is present between the first flip plate and the second flip plate; or
in the case that the support device is connected to the flexible display module and the support device is in the unfolded state, a second gap is present between the first flip plate and the second flip plate;
wherein the first gap is greater than the second gap, and a difference value between the first gap and the second gap is a length compensation value for the flexible display module.

In some embodiments, a first curved rotation groove is defined in the fixing member, and the first flip plate includes a first flip structure, the first flip structure being disposed in the first curved rotation groove and being flippable in the first curved rotation groove; and
a second curved rotation groove is defined in the slide member, and the second flip plate includes a second flip structure, the second flip structure being disposed in the second curved rotation groove and being flippable in the second curved rotation groove.

In some embodiments, the fixing member includes a first fixing branch and a second fixing branch that are opposite to each other and spaced apart from each other, the first curved rotation groove being disposed on the first fixing branch; wherein
a slide rail is arranged on each of a side, close to the second fixing branch, of the first fixing branch and a side, close to the first fixing branch, of the second fixing branch; and
a slide rail groove matching the slide rail is defined in each of two sides of the slide member, the slide member is disposed between the first fixing branch and the second fixing branch, and the slide rail of each of the first fixing branch and the second fixing branch is disposed in the slide rail groove and is slidable in the slide rail groove.

In some embodiments, the fixing member further includes: a fixing connection branch, wherein a length direction of the fixing connection branch is intersected with length directions of the first fixing branch and the second fixing branch; one end of the fixing connection branch is connected to the first fixing branch and another end of the fixing connection branch is connected to the second fixing branch; and a first connection shaft is provided at a middle position of the fixing connection branch, and one end of the first elastic member is sleeved onto the first connection shaft and connected to the fixing connection branch; and
the slide member includes an opening region, wherein a second connection shaft is arranged at a middle position of a side, away from the fixing member, of the opening region of the slide member, the first elastic member is disposed within the opening region, and another end of the first elastic member is sleeved onto the second connection shaft.

In some embodiments, the second curved rotation groove includes a first curved sub-groove and a second curved sub-groove disposed at two sides of the second connection shaft; and
the second flip structure includes a first flip substructure rotatably connected to the first curved sub-groove and a second flip substructure rotatably connected to the second curved sub-groove.

In some embodiments, a first engagement portion is arranged on a side, close to the connection wrap member, of each of the first flip substructure and the second flip substructure; and
the connection wrap member includes a second engagement portion in cooperation with the first engagement portion;
wherein in a case that the support device is in an unfolded state, a gap is present between the first engagement portion and the second engagement portion; and in a case that an angle between the first flip plate and the second flip plate is less than or equal to an angle threshold, the first engagement portion and the second engagement portion are cooperatively in direct contact with each other.

In some embodiments, the angle threshold is 170 degrees.

In some embodiments, the fixing member includes two first connection structures and the connection wrap member includes two second connection structures; and a first connection through-hole is defined in the first flip plate, and a second connection through-hole is defined in the second flip plate, both the first connection through-hole and the second connection through-hole being configured to allow screws to run through;
wherein a screw is capable of connecting one of the two first connection structures to a corresponding one of the two second connection structures upon running through the first connection through-hole, and a screw is capable of connecting another of the two first connection structures to a corresponding one of the two second connection structures upon running through the second connection through-hole.

In some embodiments, the support device further includes: a synchronization assembly, the synchronization assembly including:
a first stopper, and a first gear structure, a second gear structure, a third gear structure, and a fourth gear structure that are connected to the first stopper and are sequentially in mesh with each other;
wherein the first gear structure is slidably connected to the first flip plate and rotatably connected to the fixing member and the first stopper; the second gear structure is rotatably connected to the fixing member and the first stopper; the third gear structure is rotatably connected to the fixing member and the first stopper; the fourth gear structure is slidably connected to the second flip plate and rotatably connected to the fixing member and the first stopper.

In some embodiments, the first gear structure includes a first gear portion, a first connection rod, a first connection portion, and a first rotation portion, wherein the first gear portion is sleeved onto the first connection rod and fixedly connected to the first connection rod, the first connection portion is disposed on a side, with a gear tooth, of the first gear portion and fixedly connected to a side of the first gear portion, and the first rotation portion is fixedly connected to the first connection portion; a first slide groove is defined in the first flip plate, wherein the first rotation portion is disposed in the first slide groove and is slidable in the first slide groove; and a first connection groove is defined in a side wall of the fixing member, wherein one end of the first connection rod is rotatably connected to the first connection groove;
the second gear structure includes a second gear portion and a second connection rod, wherein the second gear portion is disposed on a side, away from the first connection portion, of the first gear portion and is in mesh with the first gear portion, and the second gear portion is sleeved onto the second connection rod and fixedly connected to the second connection rod; and a second connection groove is defined in the side wall of the fixing member, wherein one end of the second connection rod is rotatably connected to the second connection groove;
the third gear structure includes a third gear portion and a third connection rod, wherein the third gear portion is disposed on a side, away from the first gear portion, of the second gear portion and is in mesh with the second gear portion, and the third gear portion is sleeved onto the third connection rod and fixedly connected to the third connection rod; and a third connection groove is further defined in the side wall of the fixing member, wherein one end of the third connection rod is rotatably connected to the third connection groove;
the fourth gear structure includes a fourth gear portion, a fourth connection rod, a second connection portion, and a second rotation portion, wherein the fourth gear portion is disposed on a side, away from the second gear portion, of the third gear portion and is in mesh with the third gear portion, the fourth gear portion is sleeved onto the fourth connection rod and fixedly connected to the fourth connection rod, the second connection portion is disposed on a side, with a gear tooth, of the fourth gear portion and fixedly connected to a side of the fourth gear portion, and the second rotation portion is fixedly connected to the second connection portion; a second slide groove is defined in the second flip plate, wherein the second rotation portion is disposed in the second slide groove and is slidable in the second slide groove; and a fourth connection groove is defined in the side wall of the fixing member, wherein one end of the fourth connection rod is rotatably connected to the fourth connection groove; and
a first through-hole, a second through-hole, a first blind hole, and a second blind hole are defined in the first stopper, wherein the first blind hole and the second blind hole are disposed between the first through-hole and the second through-hole, the first through-hole is configured to allow another end of the first connection rod to run through, the second through-hole is configured to allow another end of the fourth connection rod to run through, another end of the second connection rod is disposed in the first blind hole, and another end of the third connection rod is disposed in the second blind hole.

In some embodiments, the hinge further includes: a torque assembly, the torque assembly including:
two friction members, wherein each of the two friction members is disposed on a side, away from the gear structures, of the first stopper and provided with a first connection hole, the first connection hole of one of the two friction members being configured to allow the first connection rod to run through, and the first connection hole of another of the two friction members being configured to allow the fourth connection rod to run through;
an uneven wheel connection structure, wherein the uneven wheel connection structure includes: a first uneven portion, a second uneven portion, and an uneven connection portion connecting the first uneven portion to the second uneven portion, wherein a second connection hole is defined in each of the first uneven portion and the second uneven portion, the second connection hole of the first uneven portion being configured to allow the first connection rod to run through, and the second connection hole of the second uneven portion being configured to allow the fourth connection rod to run through; and a side of each of the first uneven portion and the second uneven portion is a flat surface and another side of each of the first uneven portion and the second uneven portion is an uneven surface, the flat surface being close to the two friction members relative to the uneven surface;
two uneven members, wherein both the two uneven members are disposed on a side, away from the two friction members, of the uneven wheel connection structure, and a third connection hole is defined in each of the two uneven members, and a side of each of the two uneven members is a flat surface and another side of each of the two uneven members is an uneven surface, wherein the uneven surface of one of the two uneven members is in mesh with the uneven surface of the first uneven portion, and the third connection hole of the one of the two uneven members is configured to allow the first connection rod to run through; and the uneven surface of another of the two uneven members is in mesh with the uneven surface of the second uneven portion, and the third connection hole of the another of the two uneven members is configured to allow the fourth connection rod to run through;
two second elastic members, wherein one end of one of the two second elastic members is in contact with the flat surface of one of the two uneven members and is configured to allow the first connection rod to run through; and one end of another of the two second elastic members is in contact with the flat surface of another of the two uneven members and is configured to allow the fourth connection rod to run through; and
a second stopper, wherein the second stopper is disposed on a side, away from the synchronization assembly, of the two second elastic members and fixedly connected to the connection wrap member; and one end of the second stopper is in contact with another end of the one of the two second elastic members, and another end of the second stopper is in contact with another end of the another of the two second elastic members.

In some embodiments, each of the first connection rod and the second connection rod has at least one flat structure in cross-section; each of the first connection hole and the third connection hole is a flat connection hole matching the at least one flat structure; and each of the two friction members and the two uneven members is capable of rotating in sync with the first connection rod and the fourth connection rod; and
the first connection rod and the fourth connection rod are rotatable within the second connection holes, and the uneven wheel connection structure is not in sync with rotations of the first connection rod and the fourth connection rod.

In some embodiments, the second elastic member is a square spring, the square spring being a spring having a square cross-section.

In some embodiments, the flip assembly includes: two first flip plates, two fixing members, one connection wrap member, two slide members, two first elastic members, and two second flip plates.

According to another aspect, a foldable display device is provided. The foldable display device includes: a flexible display module and a support device as described in the above aspects;
wherein the support device is disposed on a non-display surface of the flexible display module and connected to the flexible display module to support the flexible display module.

### BRIEF DESCRIPTION OF DRAWINGS

For clearer descriptions of the technical solutions in the embodiments of the present disclosure, the following briefly describes the accompanying drawings required for describing the embodiments. Apparently, the accompanying drawings in the following description show merely some embodiments of the present disclosure, and those of ordinary skill in the art may still derive other drawings from these accompanying drawings without any creative efforts.

FIG. 1 is a schematic structural diagram of a flexible display module according to some embodiments of the present disclosure;

FIG. 2 is a schematic structural diagram of a support device according to some embodiments of the present disclosure;

FIG. 3 is a schematic structural diagram of a hinge in the support device shown in FIG. 2;

FIG. 4 is a partial schematic structural diagram of the hinge in the support device shown in FIG. 2;

FIG. 5 is an exploded schematic diagram of a flip assembly according to some embodiments of the present disclosure;

FIG. 6 is a schematic diagram of a support device in an unfolded state according to some embodiments of the present disclosure;

FIG. 7 is a schematic diagram of a support device and a flexible display module in an unfolded state according to some embodiments of the present disclosure;

FIG. 8 is a schematic structural diagram of a fixing member according to some embodiments of the present disclosure;

FIG. 9 is a schematic structural diagram of a first flip plate according to some embodiments of the present disclosure;

FIG. 10 is a schematic structural diagram of a slide member according to some embodiments of the present disclosure;

FIG. 11 is a schematic structural diagram of a second flip plate according to some embodiments of the present disclosure;

FIG. 12 is a schematic diagram of a fixing member and a slide member cooperating with each other according to some embodiments of the present disclosure;

FIG. 13 is a schematic structural diagram of a connection wrap member according to some embodiments of the present disclosure;

FIG. 14 is a schematic diagram of a support device in an unfolded state according to some embodiments of the present disclosure;

FIG. 15 is a schematic diagram of a support device in a folded state according to some embodiments of the present disclosure;

FIG. 16 is a diagram of a connection relationship between a fixing member and a connection wrap member according to some embodiments of the present disclosure;

FIG. 17 is a schematic diagram of a flip assembly and a synchronization assembly according to some embodiments of the present disclosure;

FIG. 18 is another schematic diagram of a flip assembly and a synchronization assembly according to some embodiments of the present disclosure;

FIG. 19 is a schematic structural diagram of a first gear structure according to some embodiments of the present disclosure;

FIG. 20 is a schematic structural diagram of a first stopper according to some embodiments of the present disclosure;

FIG. 21 is an exploded schematic diagram of a synchronization assembly and a torque assembly according to some embodiments of the present disclosure;

FIG. 22 is a schematic diagram of a synchronization assembly and a torque assembly according to some embodiments of the present disclosure;

FIG. 23 is a schematic structural diagram of a friction member according to some embodiments of the present disclosure;

FIG. 24 is a schematic structural diagram of an uneven wheel connection structure according to some embodiments of the present disclosure;

FIG. 25 is a schematic structural diagram of an uneven member according to some embodiments of the present disclosure;

FIG. 26 is a schematic structural diagram of a second stopper according to some embodiments of the present disclosure;

FIG. 27 is a cross-sectional view of a first connection rod or a fourth connection rod according to some embodiments of the present disclosure;

FIG. 28 is a cross-sectional view of a friction member according to some embodiments of the present disclosure; and

FIG. 29 is an exploded schematic diagram of a foldable display device according to some embodiments of the present disclosure.

### DETAILED DESCRIPTION

To make the objectives, technical solutions, and advantages of the present disclosure clearer, the embodiments of the present disclosure are further described in detail hereinafter with reference to the accompanying drawings.

In the related art, a foldable display device includes: a flexible display panel and a support device disposed on a side of the flexible display panel. The flexible display panel includes a bendable portion and unbendable portions disposed on two sides of the bendable portion. The support device includes a first support plate, a second support plate, and a flip assembly, the flip assembly being separately connected to the first support plate and the second support plate. Moreover, the flip assembly is configured to allow the first support plate and the second support plate to flip relative to each other, such that the two unbendable portions of the flexible display panel that are respectively fixed to the first support plate and the second support plate can rotate relative to each other, thereby achieving the folding of the display device.

However, because the length of the flexible display panel slightly changes between different states, i.e., from a folded state to an unfolded state, the display device according to the above-described scheme may have an irrecoverable crease at the boundary of the bendable portion and the unbendable portion upon a period of time, resulting in a poor display effect of the display device.

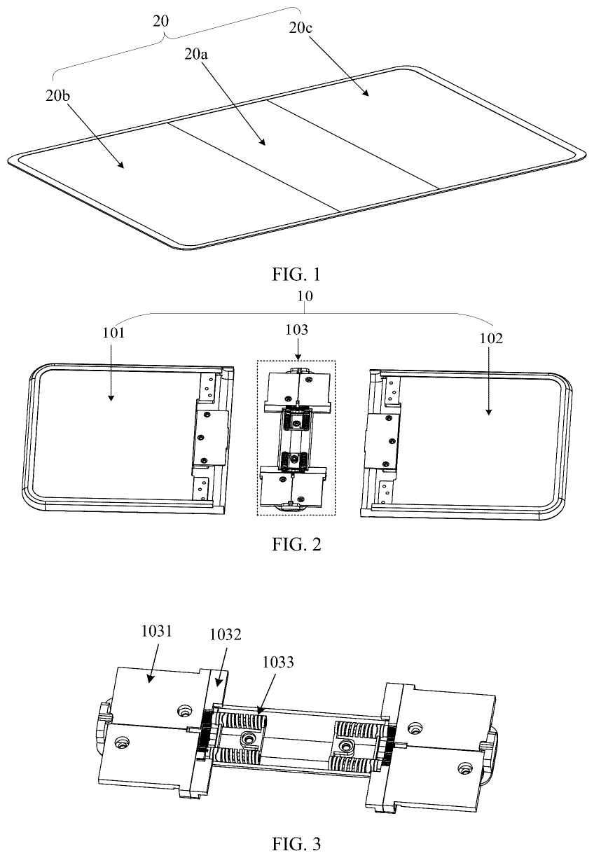

Embodiments of the present disclosure provide a support device 10 to solve the problem of poor display effect of the display device due to crease in the related art. The support device 10 is configured to be connected to the flexible display module 20, so as to support the flexible display module 20. Referring to FIG. 1, the flexible display module 20 includes a bendable portion 20a and a first unbendable portion 20b and a second unbendable portion 20c disposed on two sides of the bendable portion 20a. FIG. 2 is a schematic structural diagram of a support device according to some embodiments of the present disclosure. Referring to FIG. 2, the support device 10 includes a first support plate 101, a second support plate 102, and a hinge 103. The first support plate 101 is configured to support the first unbendable portion 20b, and the second support plate 102 is configured to support the second unbendable portion 20c.

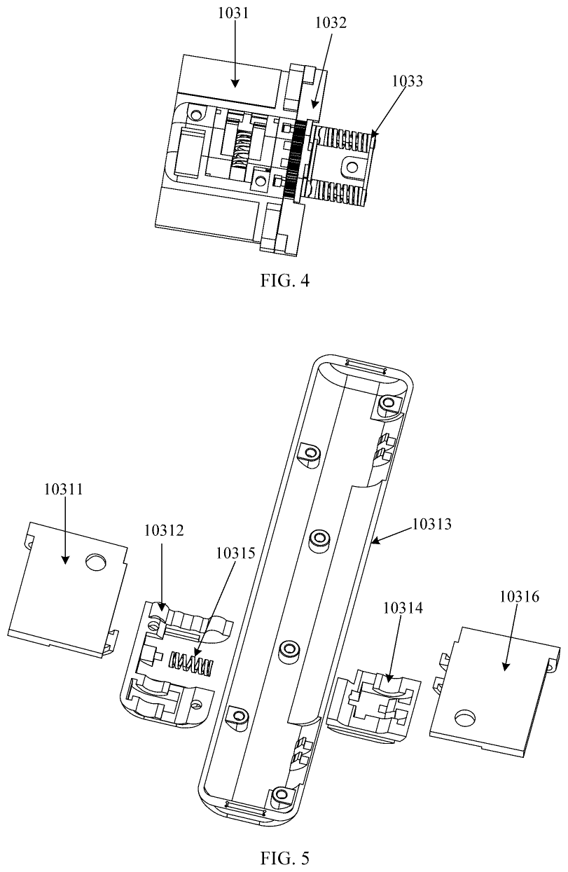

FIG. 3 is a schematic structural diagram of a hinge in the support device shown in FIG. 2. FIG. 4 is a partial schematic structural diagram of the hinge in the support device shown in FIG. 2. Referring to FIGS. 3 and 4, the hinge 103 at least includes a flip assembly 1031. FIG. 5 is an exploded schematic diagram of a flip assembly according to some embodiments of the present disclosure. In conjunction with FIGS. 4 to 5, the flip assembly 1031 includes: a first flip plate 10311, a fixing member 10312, a connection wrap member 10313, a slide member 10314, a first elastic member 10315, and a second flip plate 10316.

Referring to FIGS. 2 to 5, the first flip plate 10311 is fixedly connected to the first support plate 101, such that the first flip plate 10311 drives the first support plate 101 to rotate synchronously during the rotation of the first flip plate 10311. The fixing member 10312 is rotatably connected to the first flip plate 10311, i.e., the first flip plate 10311 is rotatable relative to the fixing member 10312. The connection wrap member 10313 wraps the fixing member 10312 and the slide member 10314, the connection wrap member 10313 is fixedly connected to the fixing member 10312, and the slide member 10314 is slidably connected to the fixing member 10312. One end of the first elastic member 10315 is connected to the fixing member 10312 and another end of the first elastic member 10315 is connected to the slide member 10314. The second flip plate 10316 is fixedly connected to the second support plate 102 and rotatably connected to the slide member 10314.

Because the first flip plate 10311 is capable of driving the first support plate 101 to rotate, and the second flip plate 10316 is capable of driving the second support plate 102 to rotate, in the case that the first flip plate 10311 rotates relative to the fixing member 10312, and the second flip plate 10316 rotates relative to the slide member 10314, the first support plate 101 and the second support plate 102 are driven to rotate relative to one another, so as to achieve folding or unfolding of the support device 10. Further, the foldable display device including the support device 10 and the flexible display module 20 is driven to be folded or unfolded. In some embodiments, in the case that the support device 10 changes from the unfolded state to the folded state, the flexible display module 20 is driven to simultaneously change from the unfolded state to the folded state (i.e., the foldable display device is folded); or in the case that the support device 10 changes from the folded state to the unfolded state, the flexible display module 20 is driven to simultaneously change from the folded state to the unfolded state (i.e., the foldable display device is unfolded.)

In the embodiments of the present disclosure, because both the fixing member 10312 and the slide member 10314 are wrapped by the connection wrap member 10313, during the sliding of the slide member 10314 relative to the fixing member 10312, the entire sliding process is confined within the space of the connection wrap member 10313. Moreover, the first elastic member 10315 is in a compressed state, and the first elastic member 10315 is separately connected to the fixing member 10312 and the slide member 10314. Therefore, the slide member 10314 slides relative to the fixing member 10312 under the elastic force of the first elastic member 10315.

In some embodiments, the elasticity of the first elastic member 10315 is positively correlated with the compression amount of the first elastic member 10315. The length of the first elastic member 10315 is negatively correlated with the compression amount of the first elastic member 10315. That is, the greater the compression amount of the first elastic member 10315, the greater the elasticity of the first elastic member 10315, the smaller the length of the first elastic member 10315; and the smaller the compression amount of the first elastic member 10315, the smaller the elasticity of the first elastic member 10315, the greater the length of the first elastic member 10315.

In the case that the flexible display module 20 enters the unfolded state under the driving of the support device 10, the slide member 10314 tends to slide along a direction away from the fixing member 10312 under the elastic force of the first elastic member 10315, which in turn causes the second flip plate 10316 connected to the slide member 10314 to provide a force for the second support plate 102 to move away from the first support plate 101, and causes the first flip plate 10311 connected to the fixing member 10312 to provide a force for the first support plate 101 to move away from the second support plate 102. Further, because the first support plate 101 and the second support plate 102 are respectively connected to the first unbendable portion 20b and the second unbendable portion 20c of the flexible display module 20, the first support plate 101 provides a force for the first unbendable portion 20b to move away from the second unbendable portion 20c, and the second support plate 102 provides a force for the second unbendable portion 20c to move away from the first unbendable portion 20b. In this way, the flexible display module 20 is able to remain flat under the combined action of the first support plate 101 and the second support plate 102.

In some embodiments of the present disclosure, the first compression amount of the first elastic member 10315 in the case where the support device 10 is not connected to the flexible display module 20 is smaller than the second compression amount of the first elastic member 10315 in the case where the support device 10 is connected to the flexible display module 20. That is, the length of the first elastic member 10315 between the slide member 10314 and the fixing member 10312 is smaller upon the support device 10 being connected to the flexible display module 20, such that the first elastic member 10315 has an elongation margin, so as to match the length change of the flexible display module 20.

Upon the foldable display device being used for a period of time, in the case that the lengths of the flexible display module 20 in the two different states of unfolded and folded are slightly different, the second compression amount of the first elastic member 10315 is reduced (i.e., the first elastic member 10315 is elongated), so as to compensate for the change in the length of the flexible display module 20. That is, in the embodiment of the present disclosure, the second compression amount of the first elastic member 10315 varies based on the length of the flexible display module 20, such that the length of the hinge 103 matches the length of the flexible display module 20, which in turn ensures the flatness of the flexible display module 20 and a better display effect.

Because the slide member 10314 and the fixing member 10312 are wrapped in the connection wrap member, the maximum sliding distance of the slide member 10314 relative to the fixing member 10312 is limited, and in turn, the maximum length of the first elastic member 10315 disposed between the slide member 10314 and the fixing member 10312 is also limited. In some embodiments, in the case that the second compression amount is reduced to the first compression amount, the sliding distance of the slide member 10314 relative to the fixing member 10312 is maximum. In this case, the length of the first elastic member 10315 is the longest, and the length compensation for the flexible display module 20 is maximized.

In summary, the embodiments of the present disclosure provide a support device. In the support device, a first support plate and a second support plate are configured to support unbendable portions of the flexible display module, and a hinge is configured to allow the bendable portion of the flexible display module to be folded or unfolded. In the case that the flexible display module enters an unfolded state under the driving of the support device, the slide member tends to slide along a direction away from the fixing member under the elastic force of the first elastic member, and thus the flexible display module is made to remain flat under the elastic force. Upon the foldable display device being used for a period of time, even lengths of the flexible display module are possible to be slightly different between two different states of unfolded and folded, the compression amount of the first elastic member is capable of gradually varying from the second compression amount to the first compression amount, so as to compensate for the change in the length of the flexible display module. As a result, the length of the hinge is made to match the length of the flexible display module, thereby ensuring the flatness of the flexible display module and a better display effect of the foldable display device.

In some embodiments, the first elastic member 10315 is a spring. In some embodiments, the first elastic member 10315 is a square spring. The square spring is a spring with a square cross-section. The reason for using the square spring as the first elasticity member 10315 is that a square spring has a larger area of cross-section than a circular spring within the same space, and thus provides a larger elasticity.

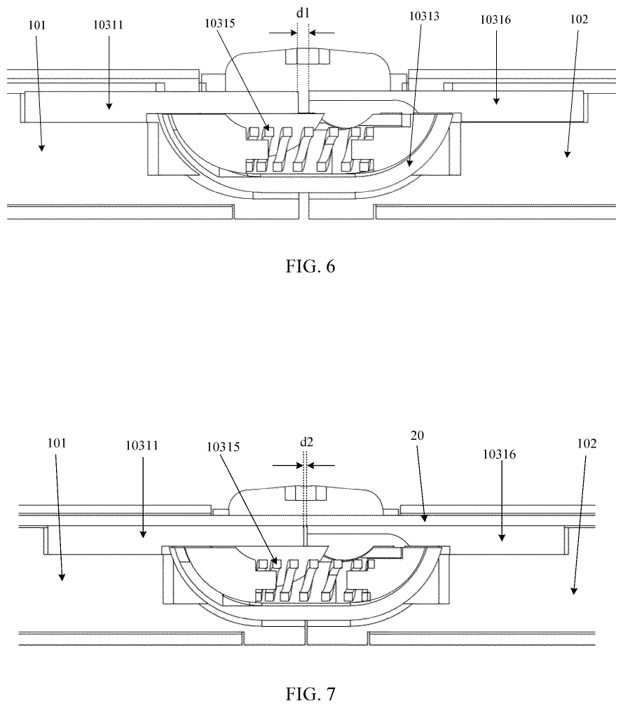

In the embodiments of the present disclosure, in the case that the support device 10 is not connected to the flexible display module 20, the slide member 10314 tends to slide along a direction away from the fixing member 10312 under the action of the elastic force of the first elastic member 10315, which in turn makes the distance between the slide member 10314 and the fixing member 10312 be the maximum distance allowed. Because both the slide member 10314 and the fixing member 10312 are disposed within the connection wrap member 10313, the slide member 10314 is only able to slide within the space of the connection wrap member 10313. As a result, the slide member 10314 is in abutment against an inner wall of the connection wrap member 10313 under the elasticity of the first elastic member 10315. Referring to FIG. 6, in the case that the support device 10 is not connected to the flexible display module 20 and the support device 10 is in the unfolded state, a first gap dl is present between the first flip plate 10311 and the second flip plate 10316.

During the process of connecting the support device 10 to the flexible display module 20, both the first support plate 101 and the second support plate 102 are pushed by an auxiliary fixture in a direction close to the hinge 103 (i.e., the distance between the first support plate 101 and the second support plate 102 is reduced), which reduces the length of the first elastic member 10315 (makes the compression amount of the first elastic member 10315 change from the first compression amount to the second compression amount.) Moreover, the support device 10 and the flexible display module 20 are connected during the push of the auxiliary fixture. As a result, the second compression amount of the first elastic member 10315 upon the support device 10 and the flexible display module 20 being connected is made greater than the first compression amount of the first elastic member 10315 in the case where the support device 10 is not connected to the flexible display module 20.

Further, because the length of the first elastic member 10315 with the second compression amount is smaller than the length of the first elastic member 10315 with the first compression amount, a gap is present between the slide member 10314 and an inner wall of the connection wrap member 10313 in the case where the support device 10 is connected to the flexible display module 20. Referring to FIG. 7, in the case that the support device 10 is in the unfolded state, a second gap d2 is present between the first flip plate 10311 and the second flip plate 10316.

In some embodiments of the present disclosure, the first gap d1 is greater than the second gap d2, and a difference value between the first gap d1 and the second gap d2 is a length compensation value for the flexible display module 20. In some embodiments, the first gap d1 ranges from 0.4 mm (millimeter) to 0.6 mm, such as 0.43 mm, 0.45 mm, 0.48 mm, 0.5 mm, 0.53 mm, 0.55 mm, or 0.58 mm. In some embodiments, the second gap d2 ranges from 0.15 mm to 0.25 mm, such as 0.18 mm, 0.2 mm, or 0.23 mm. In some embodiments, the length compensation value for the flexible display module 20 is equal to the first gap d1 minus the second gap d2, i.e., the length compensation value for the flexible display module 20 is in the range of 0.2 mm to 0.4 mm. In some embodiments, in the case where the first gap d1 is 0.5 mm and the second gap d2 is 0.2 mm, the length compensation value for the flexible display module 20 is 0.5−0.2=0.3 mm.

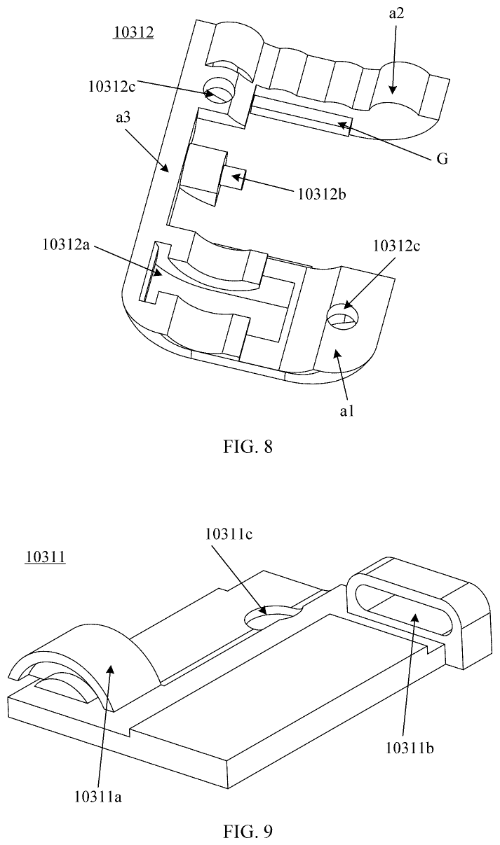

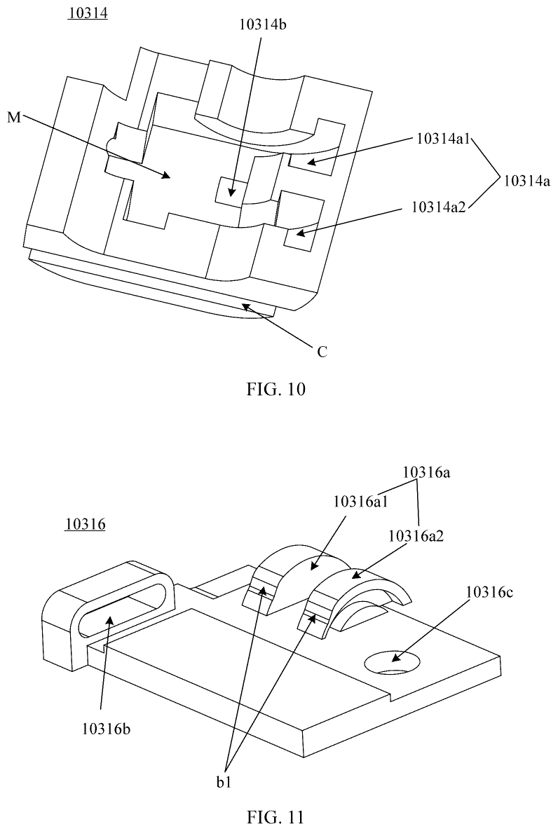

FIG. 8 is a schematic structural diagram of a fixing member according to some embodiments of the present disclosure. FIG. 9 is a schematic structural diagram of a first flip plate according to some embodiments of the present disclosure. Combining FIGS. 8 and 9, a first curved rotation groove 10312a is defined in the fixing member 10312, and the first flip plate 10311 includes a first flip structure 10311a, the first flip structure 10311a being disposed in the first curved rotation groove 10312a and being flippable in the first curved rotation groove 10312a. That is, the relative rotation of the first flip plate 10311 to the fixing member 10312 is achieved through the rotation of the first flip structure 10311a in the first curved rotation groove 10312a.

FIG. 10 is a schematic structural diagram of a slide member according to some embodiments of the present disclosure. FIG. 11 is a schematic structural diagram of a second flip plate according to some embodiments of the present disclosure. Combining FIGS. 10 and 11, a second curved rotation groove 10314a is defined in the slide member 10314, and the second flip plate 10316 has a second flip structure 10316a, the second flip structure 10316a being disposed in the second curved rotation groove 10314a and being flippable in the second curved rotation groove 10314a. That is, the relative rotation of the second flip plate 10316 to the slide member 10314 is achieved through the rotation of the second flip structure 10316a in the second curved rotation groove 10314a.

Referring to FIG. 8, the fixing member 10312 includes a first fixing branch a1 and a second fixing branch a2 that are opposite to each other and spaced apart from each other, and the first curved rotation groove 10312a is disposed on the first fixing branch a1. A slide rail G is arranged on each of a side, close to the second fixing branch a2, of the first fixing branch a1, and a side, close to the first fixing branch a1, of the second fixing branch a2. Referring to FIG. 10, a slide rail groove C matching the slide rail G is defined in each of two sides of the slide member 10314.

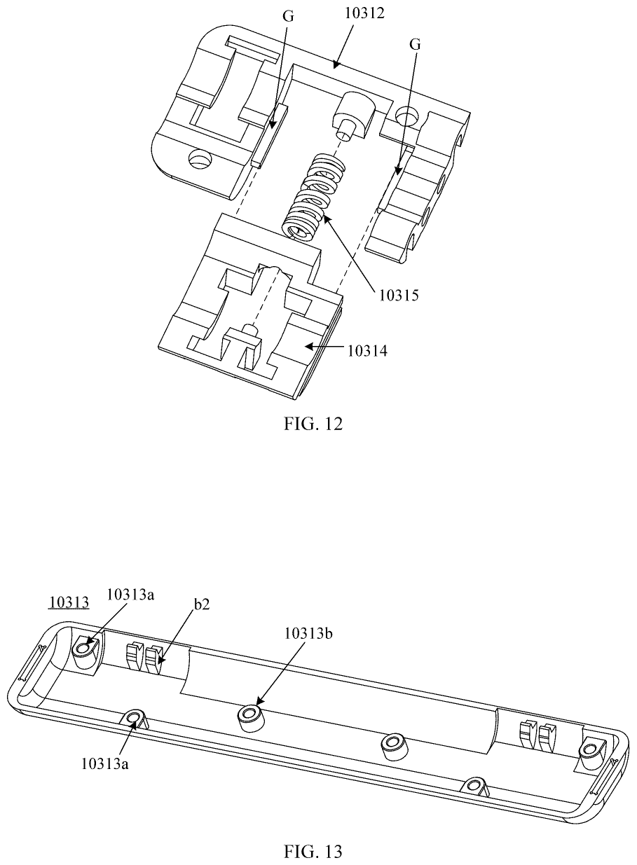

FIG. 12 is a schematic diagram of a fixing member and a slide member cooperating with each other according to some embodiments of the present disclosure. Referring to FIGS. 8, 10, and 12, the slide member 10314 is disposed between the first fixing branch a1 and the second fixing branch a2, and the slide rails G of the first fixing branch a1 and the second fixing branch a2 are respectively disposed in the slide rail grooves C on two sides of the slide member 10314 and slidable in the slide rail grooves C. That is, the relative sliding of the slide member 10314 to the fixing member 10312 is achieved through the sliding of the slide rails G in the slide rail grooves C.

In some embodiments, the slide rail G and slide rail groove C designed in the fixing member 10312 and the slide member 10314 are interchangeable. In some embodiments, the slide rail groove C is provided on each of the side, close to the second fixing branch a2, of the first fixing branch a1, and the side, close to the first fixing branch a1, of the second fixing branch a2. The slide rail G matching the slide rail groove C is disposed on each of the two sides of the slide member 10314.

Referring to FIG. 8, the fixing member 10312 further includes: a fixing connection branch a3. The length direction of the fixing connection branch a3 is intersected with length directions of the first fixing branch a1 and the second fixing branch a2. One end of the fixing connection branch a3 is connected to the first fixing branch a1 and another end of the fixing connection branch a3 is connected to the second fixing branch a2. A first connection shaft 10312b is disposed at a middle position of the fixing connection branch a3, and one end of the first elastic member 10315 is sleeved onto the first connection shaft 10312b and connected to the fixing connection branch a3.

Referring to FIG. 10, the slide member 10314 includes an opening region M, and a second connection shaft 10314b is arranged at a middle position of a side, away from the fixing member 10312, of the opening region M of the slide member 10314. The first elastic member 10315 is disposed in the opening region M, and another end of the first elastic member 10315 is sleeved onto the second connection shaft 10314b.

That is, by disposing the first connection shaft 10312b on the fixing connection branch a3 of the fixing member 10312 and disposing the second connection shaft 10314b in the opening region M of the slide member 10314, the first elastic member 10315 is connected to the fixing member 10312 and the slide member 10314.

Referring to FIG. 10, the second curved rotation groove 10314a includes a first curved sub-groove 10314a1 and a second curved sub-groove 10314a2 disposed at two sides of the second connection shaft 10314b. Correspondingly, referring to FIG. 11, the second flip structure 10316a includes a first flip substructure 10316a1 rotatably connected to the first curved sub-groove 10314a1 and a second flip substructure 10316a2 rotatably connected to the second curved sub-groove 10314a2. Both the first curved sub-groove 10314a1 and the second curved sub-groove 10314a2 are disposed within the opening region M.

Referring to FIG. 11, a first engagement portion b1 is arranged on a side, close to the connection warp member 10313 of each of the first flip substructure 10316a1 and the second flip substructure 10316a2 of the second flip plate 10316. FIG. 13 is a schematic structural diagram of a connection wrap member according to some embodiments of the present disclosure. Referring to FIG. 13, the connection wrap member 10313 includes a second engagement portion b2 in cooperation with the first engagement portion b1.

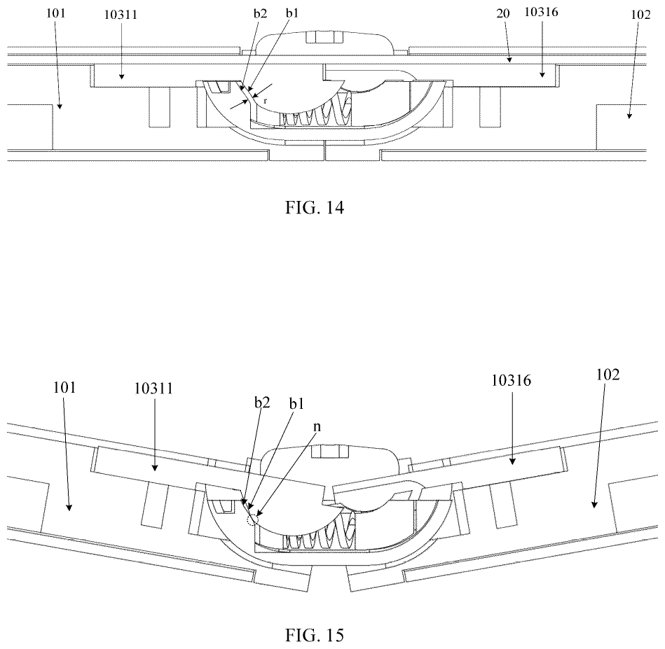

FIG. 14 is a schematic diagram of a support device in an unfolded state according to some embodiments of the present disclosure. Referring to FIG. 14, a gap r is present between the first engagement portion b1 and the second engagement portion b2. The existence of the gap r makes it possible for the first elastic member 10315 to be elongated, which in turn makes it possible for the gap between the first flip plate 10311 and the second flip plate 10316 to be increased, i.e., length compensation is provided for the flexible display module 20.

In some embodiments, the gap r between the first engagement portion b1 and the second engagement portion b2 ranges from 0.3 mm to 0.5 mm, such as 0.32 mm, 0.35 mm, 0.38 mm, 0.4 mm, 0.43 mm, 0.45 mm, or 0.48 mm. Assuming that the gap r between the first engagement portion b1 and the second engagement portion b2 is 0.3 mm, the support device 10 is able to provide a length compensation of 0.3 mm for the flexible display module 20.

Moreover, in the case that an angle between the first flip plate 10311 and the second flip plate 10316 is less than an angle threshold, the first engagement portion b1 and the second engagement portion b2 are cooperatively in direct contact with each other. In the case where the first engagement portion b1 and the second engagement portion b2 are in direct contact with each other, the second engagement portion b2 in the connection wrap member 10313 is able to push the first engagement portion b1 in the flip substructure, thereby causing the second flip plate 10316 to move along a direction close to the first flip plate 10311. As a result, during the folding process of the foldable display device, the support device 10 does not strain the flexible display module 20. That is, the support device 10 only provides tension for the flexible display module 20 in the unfolded state to eliminate creases.

FIG. 15 is a schematic diagram of a support device in a folded state according to some embodiments of the present disclosure. Referring to FIG. 15, in the case that the support device 10 is in the folded state (the angle is less than the angle threshold), the first engagement portion b1 and the second engagement portion b2 are in direct contact with each other. In FIG. 15, the contact position of the first engagement portion b1 with the second engagement portion b2 is pointed by symbol n.

In some embodiments, the angle threshold is 170° (degrees). In some embodiments, in the case that the angle between the first flip plate 10311 and the second flip plate 10316 is 170°, the gap between the first engagement portion b1 and the second engagement portion b2 is reduced to 0. Further, in the case that the angle between the first flip plate 10311 and the second flip plate 10316 is less than 170°, no gap is present between the first engagement portion b1 and the second engagement portion b2 all the time.

Moreover, during the gradual transition of the angle between the first flip plate 10311 and the second flip plate 10316 in the support device 10 from 180° to 170°, the gap between the first engagement portion b1 and the second engagement portion b2 is gradually reduced from a gap r (e.g., 0.3 mm) to zero. That is, in the case that the angle between the first flip plate 10311 and the second flip plate 10316 ranges from 170° to 180°, the gap between the first engagement portion b1 and the second engagement portion b2 gradually decreases with the decrease of the angle between the first flip plate 10311 and the second flip plate 10316.

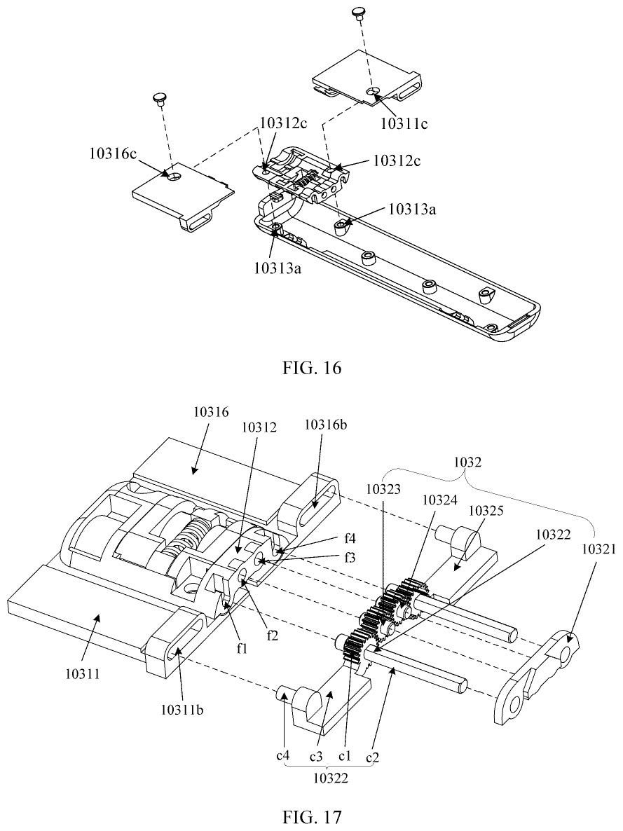

In some embodiments of the present disclosure, the fixing member 10312 and the connection wrap member 10313 are connected by screws. Referring to FIG. 16, the fixing member 10312 includes two first connection structures 10312c, and accordingly, the connection wrap member 10313 includes two second connection structures 10313a. In some embodiments, all of the first connection structures 10312c and the second connection structures 10313a are connection holes.

Moreover, a first connection through-hole 10311c is defined in the first flip plate 10311 and a second connection through-hole 10316c is defined in the second flip plate 10316. A screw is capable of connecting one of the two first connection structures 10312c to a corresponding one of the two second connection structures 10313a upon running through the first connection through-hole 10311c, and another screw is capable of connecting another of the two first connection structures 10312c to a corresponding one of the two second connection structures 10313a upon running through the second connection through-hole 10316c. That is, the first connection through-hole 10311c on the first flip plate 10311 and the second connection through-hole 10316c on the second flip plate 10316 are holes for screws to pass through, and do not connect the flip plate to the fixing member 10312.

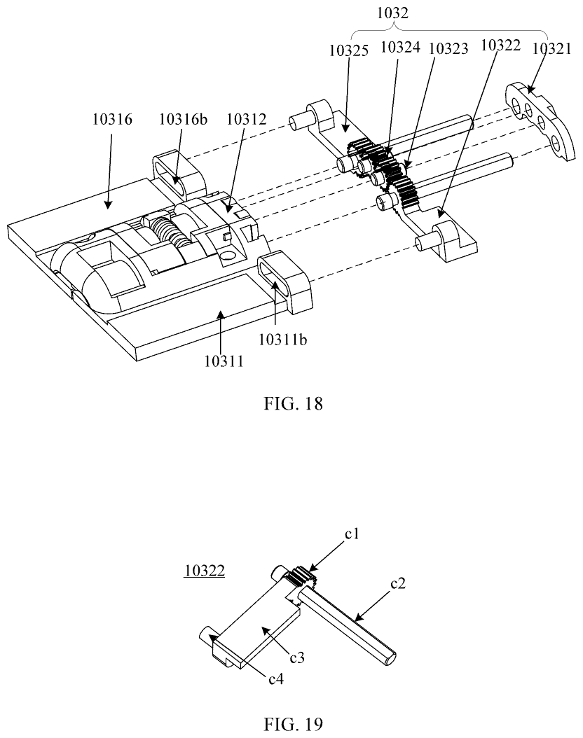

In some embodiments of the present disclosure, referring to FIGS. 3 and 4, the support device 10 further includes a synchronization assembly 1032. FIG. 17 is a schematic diagram of a flip assembly and a synchronization assembly according to some embodiments of the present disclosure. FIG. 18 is another schematic diagram of a flip assembly and a synchronization assembly according to some embodiments of the present disclosure. Referring to FIGS. 17 and 18, the synchronization assembly 1032 includes: a first stopper 10321, and a first gear structure 10322, a second gear structure 10323, a third gear structure 10324, and a fourth gear structure 10325 that are connected to the first stopper 10321 and are sequentially in mesh with each other.

The first gear structure 10322 is slidably connected to the first flip plate 10311 and rotatably connected to the fixing member 10312 and the first stopper 10321. The second gear structure 10323 is rotatably connected to the fixing member 10312 and the first stopper 10321. The third gear structure 10324 is rotatably connected to the fixing member 10312 and the first stopper 10321. The fourth gear structure 10325 is slidably connected to the second flip plate 10316 and is connected to the fixing member 10312 and the first stopper 10321.

Because the first gear structure 10322 is slidably connected to the first flip plate 10311 and the fourth gear structure 10325 is slidably connected to the second flip plate 10316, in the case that the first flip plate 10311 and the second flip plate 10316 rotate relative to each other, the first gear structure 10322 and the fourth gear structure 10325 in the synchronization assembly 1032 synchronously rotate, and thus the second gear structure 10323 and the third gear structure 10324 that engage with the first gear structure 10322 and the fourth gear structure 10325 also rotate synchronously. In this way, the synchronization assembly 1032 and the flip assembly 1031 synchronously rotate, so as to achieve the folding of the support device 10.

FIG. 19 is a schematic structural diagram of a first gear structure according to some embodiments of the present disclosure. Referring to FIG. 19, the first gear structure 10322 includes a first gear portion c1, a first connection rod c2, a first connection portion c3, and a first rotation portion c4. The first gear portion c1 is sleeved onto the first connection rod c2 and fixedly connected to the first connection rod c2. The first connection portion c3 is disposed on a side, with a gear tooth, of the first gear portion c1 and fixedly connected to a side of the first gear portion c1. The first rotation portion c4 is fixedly connected to the first connection portion c3.

Referring to FIGS. 17 and 19, a first slide groove 10311b is defined in the first flip plate 10311, and the first rotation portion c4 is disposed in the first slide groove 10311b and is slidable in the first slide groove 10311b. A first connection groove f1 is defined in a side wall of the fixing member 10312, and one end of the first connection rod c2 is rotatably connected to the first connection groove f1.

The second gear structure 10323 includes a second gear portion and a second connection rod. The second gear portion is disposed on a side, away from the first connection portion c3, of the first gear portion c1 and is in mesh with the first gear portion c1. The second gear portion is sleeved onto the second connection rod and fixedly connected to the second connection rod. A second connection groove f2 is further defined in the side wall of the fixing member 10312, and one end of the second connection rod is rotatably connected to the second connection groove f2.

The third gear structure 10324 includes a third gear portion and a third connection rod. The third gear portion is disposed on a side, away from the first gear portion c1, of the second gear portion and is in mesh with the second gear portion. The third gear portion is sleeved onto the third connection rod and fixedly connected to the third connection rod. A third connection groove f3 is further defined in the side wall of the fixing member 10312, and one end of the third connection rod is rotatably connected to the third connection groove f3.

In some embodiments, the specific design for the fourth gear structure 10325 is similar to the first gear structure 10322, and the fourth gear structure 10325 is not illustrated with a separate drawing in the embodiments of the present disclosure. The fourth gear structure 10325 includes a fourth gear portion, a fourth connection rod, a second connection portion, and a second rotation portion. The fourth gear portion is disposed on a side, away from the second gear portion, of the third gear portion and is in mesh with the third gear portion. The fourth gear portion is sleeved onto the fourth connection rod and fixedly connected to the fourth connection rod. The second connection portion is disposed on a side, with a gear tooth, of the fourth gear portion and fixedly connected to a side of the fourth gear portion. The second rotation portion is fixedly connected to the second connection portion. A second slide groove 10316b is defined in the second flip plate 10316, and the second rotation portion is disposed in the second slide groove 10316b and is slidable in the second slide groove 10316b. A fourth connection groove f4 is defined in the side wall of the fixing member 10312, and one end of the fourth connection rod is rotatably connected to the fourth connection groove f4.

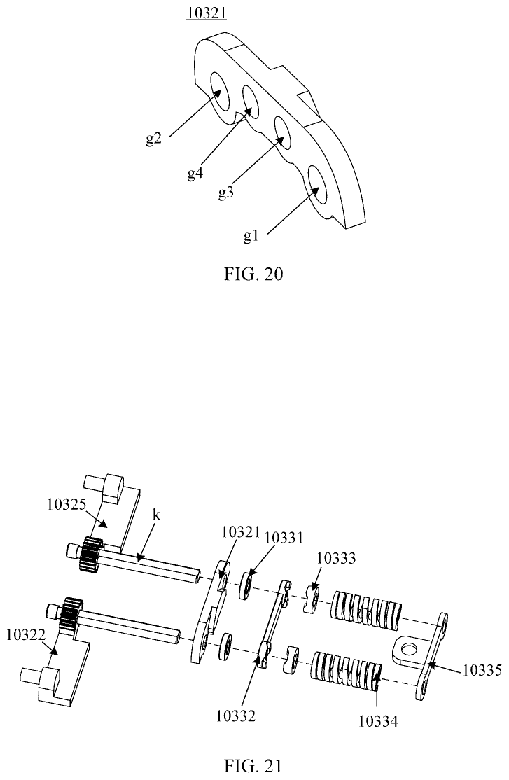

Referring to FIG. 20, a first through-hole g1, a second through-hole g2, a first blind hole g3, and a second blind hole g4 are defined in the first stopper 10321. The first blind hole g3 and the second blind hole g4 are disposed between the first through-hole g1 and the second through-hole g2. The first through-hole g1 is configured to allow another end of the first connection rod c2 to run through, and the second through-hole g2 is configured to allow another end of the fourth connection rod to run through. Another end of the second connection rod is disposed in the first blind hole g3 and another end of the third connection rod is disposed in the second blind hole g4.

In some embodiments of the present disclosure, referring to FIGS. 3 and 4, the hinge 103 further includes: a torque assembly 1033. FIG. 21 is an exploded schematic diagram of a synchronization assembly and a torque assembly according to some embodiment of the present disclosure. Referring to FIG. 21, the torque assembly 1033 includes: two friction members 10331, an uneven wheel connection structure 10332, two uneven members 10333, two second elastic members 10334, and a second stopper 10335.

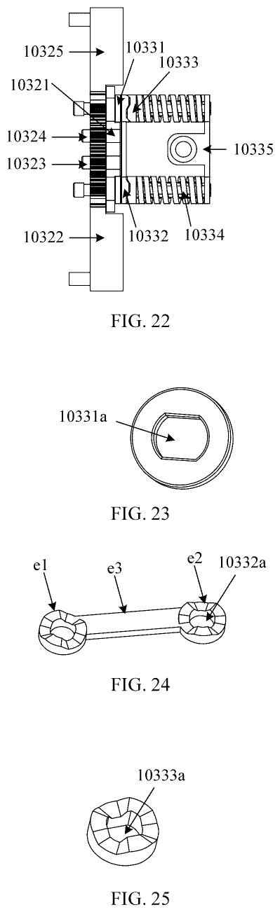

FIG. 22 is a schematic diagram of a synchronization assembly and a torque assembly according to some embodiments of the present disclosure. In conjunction with FIGS. 21 and 22, both the two friction members 10331 are disposed on a side, away from the gear structures, of the first stopper 10321.

FIG. 23 is a schematic structural diagram of a friction member according to some embodiments of the present disclosure. Referring to FIG. 23, a first connection hole 10331a is defined in each of the two friction members 10331. The first connection hole 10331a of one of the two friction members 10331 is configured to allow the first connection rod c2 to run through, and the first connection hole 10331a of another of the two friction members 10331 is configured to allow the fourth connection rod to run through. In this way, a surface of the friction member 10331 is in contact with a surface of the first stopper 10321.

FIG. 24 is a schematic structural diagram of an uneven wheel connection structure according to some embodiments of the present disclosure. Referring to FIG. 24, the uneven wheel connection structure 10332 includes: a first uneven portion e1, a second uneven portion e2, and an uneven connection portion e3 connecting the first uneven portion e1 to the second uneven portion e2. A second connection hole 10332a is defined in each of the first uneven portion e1 and the second uneven portion e2. The second connection hole 10332a of the first uneven portion e1 is configured to allow the first connection rod c2 to run through, and the second connection hole 10332a of the second uneven portion e2 is configured to allow the fourth connection rod to run through. A side of each of the first uneven portion e1 and the second uneven portion e2 is a flat surface and another side of each of the first uneven portion e1 and the second uneven portion e2 is an uneven surface. The flat surface is close to the friction member 10331 relative to the uneven surface. i.e., each of the flat surfaces of the first uneven portion e1 and the second uneven portion e2 is in contact with another surface of the friction member 10331.

FIG. 25 is a schematic structural diagram of an uneven member according to some embodiments of the present disclosure. Referring to FIGS. 22 and 25, both the two uneven members 10333 are disposed on a side, away from the friction member 10331, of the uneven wheel connection structure 10332, and a third connection hole 10333a is defined in each of the two uneven members 1033. Each uneven member 10333 has a side being a flat surface and another side being an uneven surface. The uneven surface of one of the two uneven members 10333 is in mesh with the uneven surface of the first uneven portion e1, and the third connection hole 10333a of the uneven member 10333 is configured to allow the first connection rod c2 to run through. The uneven surface of another of the two uneven members 10333 is in mesh with the uneven surface of the second uneven portion e2 and the third connection hole 10333a of the uneven member 10333 is configured to allow the fourth connection rod to run through.

One end of one of the two second elastic members 10334 is in contact with the flat surface of one of the two uneven members 10333 and is configured to allow the first connection rod c2 to run through. One end of another of the two second elastic members 10334 is in contact with the flat surface of another of the two uneven members 10333 and is configured to allow the fourth connection rod to run through. The second elastic member 10334 is configured to provide a push force for the friction member 10331, the uneven wheel connection structure 10332, and the uneven member 10333, which in turn allows the support device to stop at any time during the folding or unfolding process with the help of the friction generated by the push force. In some embodiments, the function of stopping at any time means that the first support plate 101 and the second support plate 102 in the support device are capable of stopping at any angle.

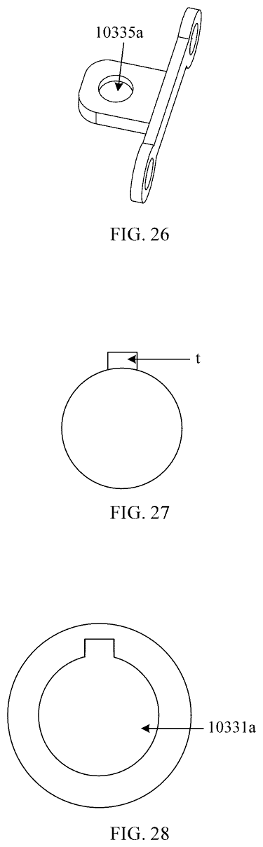

FIG. 26 is a schematic structural diagram of a second stopper according to some embodiments of the present disclosure. Referring to FIG. 22 and FIG. 26, the second stopper 10335 is disposed on a side, away from the synchronization assembly 1032, of the two second elastic members 10334 and fixedly connected to the connection wrap member 10313. In some embodiments, in conjunction with FIGS. 13 and 26, the second stopper 10335 includes a third connection structure 10335a, and the connection wrap member 10313 includes a fourth connection structure 10313b. Both the third connection structure 10335a and the fourth connection structure 10313b are connection holes, and a screw runs through the third connection structure 10335a and connects to the fourth connection structure 10313b. One end of the second stopper 10335 is in contact with another end of one of the two second elastic members 10334, and another end of the second stopper 10335 is in contact with another end of another of the two second elastic members 10334.

Referring to FIG. 21, the first connection rod c2 and the fourth connection rod have at least one flat structure k in cross-section, e.g. with two flat structures k opposite to each other. That is, the first connection rod c2 and the fourth connection rod have a non-circular shape in cross-section. Referring to FIGS. 23 and 25, each of the first connection hole 10331a and the third connection hole 10333a is a flat connection hole matching the at least one flat structure k. That is, the first connection hole 10331a and the third connection hole 10333a are non-circular holes.

Through the cooperation of the flat structure k and the flat connection hole, each of the two friction members 10331 and the two uneven members 10333 is capable of rotating in sync with the first connection rod c2 and the fourth connection rod. In other words, the friction member is capable of moving along the axial direction of the connection rod but cannot rotate relative to the connection rod. Thus, the rotational movement of the friction member relative to the first stopper 10321 provides a portion of twisting force. Moreover, the uneven member 10333 is capable of moving along the axial direction of the connection rod but cannot rotate relative to the connection rod. As a result, the rotational movement of the uneven member 10333 relative to the uneven wheel connection structure 10332 further provides a portion of the twisting force. The sum of the portions of twisting force of the friction member 10331 and the uneven member 10333 is the total friction torsion.

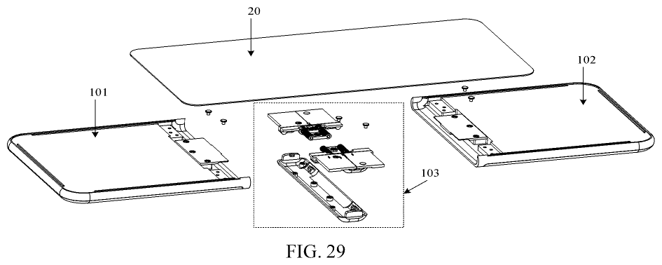

In some embodiments of the present disclosure, referring to FIG. 27, each of the first connection rod c2 and the fourth connection rod includes a raised structure in cross-section. Accordingly, in some embodiments, referring to FIG. 28, the first connection hole 10331a is a raised connection hole matching the raised structure. The cooperation of the raised structure and the raised connection hole enables the friction member 10331 to rotate synchronously with the first connection rod c2 and the fourth connection rod. In some embodiments, the third connection hole 10333a of the uneven member 10333 is similar to the first connection hole 10331a, which is not illustrated with a drawing in the embodiments of the present disclosure.

The embodiments of the present disclosure do not limit the specific shapes of the first connection rod c2, the fourth connection rod, the first connection hole 10331a, and the third connection hole 10333a, only need to ensure that the friction member 10331 and the uneven member 10333 are capable of rotating in sync with the first connection rod c2 and the fourth connection rod.

In some embodiments, the second connection hole 10332a in each of the first uneven portion e1 and the second uneven portion e2 of the uneven wheel connection structure 10332 is a circular hole, and the first connection rod c2 and the fourth connection rod are rotatable in the second connection hole 10332a. That is, the uneven wheel connection structure 10332 is not in sync with rotations of the first connection rod c2 and the fourth connection rod.

In the embodiments of the present disclosure, during the rotation of the first connection rod c2 and the fourth connection rod, a twisting force is generated between the friction member and the first stopper 10321, a twisting force is generated between the friction member 10331 and the uneven wheel connection structure 10332, and a twisting force is generated between the uneven member 10333 and the uneven wheel connection structure 10332. That is, by disposing the friction member 10331 in the torque assembly 1033 of the support device 10, the total frictional torsion is increased. The greater the total frictional torsion, the better the stop-at-any-time function (the support device is capable of stopping at any angle during the folding or unfolding process) of the foldable product can be met. Moreover, the greater total friction torsion facilitates solving the problem that a large torsion needs to be provided with a small space occupation by the hinge. Therefore, the present disclosure is in line with the development direction of lightening and thinning of the foldable product.

In some embodiments, the second elasticity member 10334 is a spring. In some embodiments, the second elasticity member 10334 is a square spring, which is a spring with a square cross-section. The reason for using the square spring as the second elastic member 10334 is that a square spring has a greater area of cross-section than a circular spring with the same space and thus provides a larger elastic force.

The greater the elasticity of the second elasticity member 10334, the greater the friction between the friction member 10331 and the uneven wheel connection structure 10332, and between the uneven wheel connection structure 10332 and the uneven member 10333 during the folding and unfolding of the support device 10. The greater the friction, the greater the resulting torsion. In this way, the problem that a large torsion needs to be provided with a small space occupation by the hinge is solved, and thus the present disclosure is in line with the development direction of lightening and thinning of the foldable product.

In some embodiments of the present disclosure, both the first support plate 101 and the second support plate 102 are fixedly connected to the hinge 103 by screws. The flexible display module 20 is affixed to the first support plate 101 and the second support plate 102 by double-sided adhesive. In the case that the flexible display module 20 enters the unfolded state (the angle between the first support plate 101 and the second support plate 102 being 180°) under the driving of the support device 10, the first elastic member 10315 is capable of pushing the slide member 10314 to slide, thereby increasing the distance between the first support plate 101 and the second support plate 102, and providing tension to eliminate creases on the flexible display module 20. During the transition of the flexible display module 20 from the unfolded state to the folded state (the angle between the first support plate 101 and the second support plate 102 gradually transitioning from 180° to 170°) under the driving of the support device 10, the distance between the first support plate 101 and the second support plate 102 gradually decreases, which in turn causes the tension to gradually decrease. Until the angle between the first support plate 101 and the second support plate 102 reaching 170°, the tension is reduced to zero. In the case that the flexible display module 20 enters a folded state (the angle between the first support plate 101 and the second support plate 102 being less than 170°) under the driving of the support device 10, the tension is maintained as zero all the time, i.e., the first support plate 101 and the second support plate 102 do not provide tension to the flexible display module 20.

In summary, the embodiments of the present disclosure provide a support device. In the support device, a first support plate and a second support plate are configured to support unbendable portions of the flexible display module, and a hinge is configured to allow the bendable portion of the flexible display module to be folded or unfolded. In the case that the flexible display module enters an unfolded state under the driving of the support device, the slide member tends to slide along a direction away from the fixing member under the elastic force of the first elastic member, and thus the flexible display module is made to remain flat under the elastic force. Upon the foldable display device being used for a period of time, even lengths of the flexible display module are possible to be slightly different between two different states of unfolded and folded, the compression amount of the first elastic member is capable of gradually varying from the second compression amount to the first compression amount, so as to compensate for the change in the length of the flexible display module. As a result, the length of the hinge is made to match the length of the flexible display module, thereby ensuring the flatness of the flexible display module and a better display effect of the foldable display device.

The embodiments of the present disclosure further provide a foldable display device. Referring to FIG. 29, the foldable display device includes a flexible display module 20 and a support device 10 as described in the above embodiments. The support device 10 is disposed on a non-display surface of the flexible display module 20 and connected to the flexible display module 20. The support device 10 is configured to support the flexible display module 20.

In some embodiments, a substrate in the flexible display module 20 is made of ultra-thin flexible glass (UTG), thereby ensuring that the foldable display device is thinner and lighter.

Moreover, in some embodiments, the folding mode of the foldable display device is U-shaped folding, i.e., the hinge in the support device 10 is a U-shaped foldable hinge. Relative to the drop-shaped foldable hinge, the U-shaped foldable hinge not only has a simpler hinge structure and has a cost of 50% of the cost of the drop-shaped foldable hinge, but also can satisfy the folding demand as well.

In some embodiments of the present disclosure, in conjunction with FIGS. 2, 3, and 29, the flip assembly 1031 of the hinge 103 includes two first flip plates 10311, two fixing members 10312, two slide members 10314, two first elastic members 10315, and two second flip plates 10316. The flip assembly 1031 includes one connection wrap member 10313. Further, the hinge 103 includes two synchronization assemblies 1032 and two torque assemblies 1033.

In some embodiments, the two first flip plates 10311, the two fixing members 10312, the two slide members 10314, the two first elastic members 10315, and the two second flip plates 10316 included in the flip assembly 1031, the two synchronization assemblies 1032, and the two torque assemblies 1033 share the same one connection wrap member 10313.

Because the foldable display device has essentially the same technical effect as the support device described in the previous embodiments, the technical effect of the foldable display device is not repeated herein for brevity.

It should be noted that although the terms “first,” “second,” or the like are used herein to describe various elements, components, regions, layers, and/or portions, these elements, components, regions, layers, and/or portions should not be limited by these terms. These terms are only used to distinguish one element, component, region, layer, or portion from another region, layer, or portion. Thus, a first element, component, region, layer, or portion discussed above may be referred to as a second element, component, region, layer, or portion without departing from the teachings of the present disclosure.

Spatially relative terms such as “under,” “on,” “left,” “right,” or the like are used herein to describe the relationship between one element or feature and another element or feature (or other elements or features) as illustrated in the drawings. It is understood that these spatially relative terms are intended to cover different orientations of the device in use or operation in addition to the orientation depicted in the drawings. In some embodiments, in the case that a device in the drawing is turned over, a component described as “under another component or feature” is orientated as “on another component or feature.” Thus, the exemplary term “under” includes two orientations of “on” and “under.” The device may be orientated in other ways (rotated 90 degrees or in other orientations) and the spatially relative descriptors used herein are interpreted accordingly. It is also understood that in the case that a layer is referred to as “between two layers”, the layer is the only layer between the two layers, or there are one or more intermediate layers.

The terms used in the present disclosure are only for the purpose of describing particular embodiments but are not intended to limit the present disclosure. As used herein, the singular forms “one,” “a,” and “the” are intended to include the plural form as well, unless the context clearly indicates otherwise. It is further understood that the terms “include” and/or “comprise” when used in the description indicate the presence of the described feature, whole, step, operation, element, and/or component, but do not exclude the presence or addition of one or more other features, wholes, steps, operations, components, parts, and/or groups thereof. As used herein, the phrase “and/or” includes any or all combinations of one or more of the associated listed items. In this description, specific features, structures, materials, or characteristics described may be properly combined in any one or more embodiments or examples. In addition, without contradicting each other, those skilled in the art may integrate and combine different embodiments or examples and features of different embodiments or examples described in this description.

Unless otherwise defined, all terms used herein (including technical and scientific terms) have the same meaning as commonly understood by those of ordinary skill in the art to which this disclosure belongs. It is further understood that terms such as those defined in commonly used dictionaries should be construed as having a meaning consistent with their meaning in the relevant field and/or context of this description, and is not construed in an idealized or overly formal sense unless expressly defined as such herein.

The above descriptions are only some embodiments of the present disclosure and are not intended to limit the present disclosure. Any modifications, equivalent substitutions, improvements, etc. made within the concept and principles of the present disclosure shall fall within the protection scope of the present disclosure.

1. A support device, configured to be connected to a flexible display module to support the flexible display module, the flexible display module comprising a bendable portion and a first unbendable portion and a second unbendable portion disposed on two sides of the bendable portion; wherein
the support device comprises:
a first support plate, configured to support the first unbendable portion;
a second support plate, configured to support the second unbendable portion; and
a hinge, configured to allow the bendable portion to be folded or unfolded;
wherein the hinge at least comprises a flip assembly, the flip assembly comprising:
a first flip plate, fixedly connected to the first support plate;
a fixing member, rotatably connected to the first flip plate;
a connection wrap member, wrapping the fixing member and fixedly connected to the fixing member;
a slide member, wrapped by the connection wrap member and slidably connected to the fixing member;
a first elastic member, disposed between the fixing member and the slide member, wherein one end of the first elastic member is connected to the fixing member and another end of the first elastic member is connected to the slide member; and
a second flip plate, fixedly connected to the second support plate and rotatably connected to the slide member;
wherein the first elastic member is in a compressed state, and a first compression amount of the first elastic member in a case where the support device is not connected to the flexible display module is less than a second compression amount of the first elastic member in a case where the support device is connected to the flexible display module.

2. The support device according to claim 1, wherein
in the case that the support device is not connected to the flexible display module, the slide member is in abutment against an inner wall of the connection wrap member under an elastic force of the first elastic member; or
in the case that the support device is connected to the flexible display module, a gap is present between the slide member and an inner wall of the connection wrap member.

3. The support device according to claim 1, wherein
in the case that the support device is not connected to the flexible display module and the support device is in an unfolded state, a first gap is present between the first flip plate and the second flip plate; or
in the case that the support device is connected to the flexible display module and the support device is in an unfolded state, a second gap is present between the first flip plate and the second flip plate;
wherein the first gap is greater than the second gap, and a difference value between the first gap and the second gap is a length compensation value for the flexible display module.

4. The support device according to claim 1, wherein
a first curved rotation groove is defined in the fixing member, and the first flip plate comprises a first flip structure, wherein the first flip structure is disposed in the first curved rotation groove and is flippable in the first curved rotation groove; and
a second curved rotation groove is defined in the slide member and the second flip plate has a second flip structure, wherein the second flip structure is disposed in the second curved rotation groove and is flippable in the second curved rotation groove.

5. The support device according to claim 4, wherein
the fixing member comprises a first fixing branch and a second fixing branch that are opposite to each other and spaced apart from each other, wherein the first curved rotation groove is disposed on the first fixing branch; wherein
a slide rail is arranged on each of a side, close to the second fixing branch, of the first fixing branch and a side, close to the first fixing branch, of the second fixing branch; and
a slide rail groove matching the slide rail is defined in each of two sides of the slide member, the slide member is disposed between the first fixing branch and the second fixing branch, and the slide rail of each of the first fixing branch and the second fixing branch is disposed in the slide rail groove and is slidable in the slide rail groove.

6. The support device according to claim 5, wherein
the fixing member further comprises a fixing connection branch, wherein
a length direction of the fixing connection branch is intersected with length directions of the first fixing branch and the second fixing branch;
one end of the fixing connection branch is connected to the first fixing branch and another end of the fixing connection branch is connected to the second fixing branch; and
a first connection shaft is disposed at a middle position of the fixing connection branch, and one end of the first elastic member is sleeved onto the first connection shaft and connected to the fixing connection branch; and
the slide member comprises an opening region, wherein a second connection shaft is arranged at a middle position of a side, away from the fixing member, of the opening region of the slide member, the first elastic member is disposed within the opening region, and another end of the first elastic member is sleeved onto the second connection shaft.

7. The support device according to claim 6, wherein
the second curved rotation groove comprises a first curved sub-groove and a second curved sub-groove at two sides of the second connection shaft; and
the second flip structure comprises a first flip substructure rotatably connected to the first curved sub-groove and a second flip substructure rotatably connected to the second curved sub-groove.

8. The support device according to claim 7, wherein
a first engagement portion is arranged on a side, close to the connection wrap member, of each of the first flip substructure and the second flip substructure; and
the connection wrap member comprises a second engagement portion in cooperation with the first engagement portion;
wherein in a case that the support device is in an unfolded state, a gap is present between the first engagement portion and the second engagement portion; and in a case that an angle between the first flip plate and the second flip plate is less than or equal to an angle threshold, the first engagement portion and the second engagement portion are cooperatively in direct contact with each other.

9. The support device according to claim 8, wherein the angle threshold is 170 degrees.

10. The support device according to claim 1, wherein the fixing member comprises two first connection structures and the connection wrap member comprises two second connection structures; and a first connection through-hole is defined in the first flip plate and a second connection through-hole is defined in the second flip plate, wherein both the first connection through-hole and the second connection through-hole are configured to allow screws to run through;
wherein a screw is capable of connecting one of the two first connection structures to a corresponding one of the two second connection structures upon running through the first connection through-hole, and a screw is capable of connecting another of the two first connection structures to a corresponding one of the two second connection structures upon running through the second connection through-hole.

11. The support device according to claim 1, wherein the support device further comprises a synchronization assembly; wherein the synchronization assembly comprises:
a first stopper, and a first gear structure, a second gear structure, a third gear structure, and a fourth gear structure that are connected to the first stopper and are sequentially in mesh with each other;
wherein the first gear structure is slidably connected to the first flip plate and rotatably connected to the fixing member and the first stopper; the second gear structure is rotatably connected to the fixing member and the first stopper; the third gear structure is rotatably connected to the fixing member and the first stopper; the fourth gear structure is slidably connected to the second flip plate and rotatably connected to the fixing member and the first stopper.

12. The support device according to claim 11, wherein
the first gear structure comprises a first gear portion, a first connection rod, a first connection portion, and a first rotation portion, wherein the first gear portion is sleeved onto the first connection rod and fixedly connected to the first connection rod, the first connection portion is disposed on a side, with a gear tooth, of the first gear portion and fixedly connected to a side of the first gear portion, and the first rotation portion is fixedly connected to the first connection portion; a first slide groove is defined in the first flip plate, wherein the first rotation portion is disposed in the first slide groove and is slidable in the first slide groove; and a first connection groove is defined in a side wall of the fixing member, wherein one end of the first connection rod is rotatably connected to the first connection groove;
the second gear structure comprises a second gear portion and a second connection rod, wherein the second gear portion is disposed on a side, away from the first connection portion, of the first gear portion and is in mesh with the first gear portion, and the second gear portion is sleeved onto the second connection rod and fixedly connected to the second connection rod; and a second connection groove is further defined in the side wall of the fixing member, wherein one end of the second connection rod is rotatably connected to the second connection groove;
the third gear structure comprises a third gear portion and a third connection rod, wherein the third gear portion is disposed on a side, away from the first gear portion, of the second gear portion and is in mesh with the second gear portion, and the third gear portion is sleeved onto the third connection rod and fixedly connected to the third connection rod; and a third connection groove is defined in the side wall of the fixing member, wherein one end of the third connection rod is rotatably connected to the third connection groove;
the fourth gear structure comprises a fourth gear portion, a fourth connection rod, a second connection portion, and a second rotation portion, wherein the fourth gear portion is disposed on a side, away from the second gear portion, of the third gear portion and is in mesh with the third gear portion, the fourth gear portion is sleeved onto the fourth connection rod and fixedly connected to the fourth connection rod, the second connection portion is disposed on a side, with a gear tooth, of the fourth gear portion and fixedly connected to a side of the fourth gear portion, and the second rotation portion is fixedly connected to the second connection portion; a second slide groove is defined in the second flip plate, wherein the second rotation portion is disposed in the second slide groove and is slidable in the second slide groove; and a fourth connection groove is defined in the side wall of the fixing member, wherein one end of the fourth connection rod is rotatably connected to the fourth connection groove; and
a first through-hole, a second through-hole, a first blind hole, and a second blind hole are defined in the first stopper, wherein the first blind hole and the second blind hole are disposed between the first through-hole and the second through-hole, the first through-hole is configured to allow another end of the first connection rod to run through, the second through-hole is configured to allow another end of the fourth connection rod to run through, another end of the second connection rod is disposed in the first blind hole, and another end of the third connection rod is disposed in the second blind hole.

13. The support device according to claim 12, wherein the hinge further comprises: a torque assembly, the torque assembly comprising:
two friction members, wherein each of the two friction members is disposed on a side, away from the gear structures, of the first stopper and provided with a first connection hole, wherein the first connection hole of one of the two friction members is configured to allow the first connection rod to run through, and the first connection hole of another of the two friction members is configured to allow the fourth connection rod to run through;
an uneven wheel connection structure, wherein the uneven wheel connection structure comprises: a first uneven portion, a second uneven portion, and an uneven connection portion connecting the first uneven portion to the second uneven portion, wherein
a second connection hole is defined in each of the first uneven portion and the second uneven portion, wherein the second connection hole of the first uneven portion is configured to allow the first connection rod to run through, and the second connection hole of the second uneven portion is configured to allow fourth connection rod to run through; and
one side of each of the first uneven portion and the second uneven portion is a flat surface and another side of each of the first uneven portion and the second uneven portion is an uneven surface, the flat surface being close to the two friction members relative to the uneven surface;
two uneven members, wherein both the two uneven members are disposed on a side, away from the two friction members, of the uneven wheel connection structure, and a third connection hole is defined in each of the two uneven members, and one side of each of the two uneven members is a flat surface and another side of each of the two uneven members is an uneven surface, wherein
the uneven surface of one of the two uneven members is in mesh with the uneven surface of the first uneven portion, and the third connection hole of the one of the two uneven members is configured to allow the first connection rod to run through; and
the uneven surface of another of the two uneven members is in mesh with the uneven surface of the second uneven portion, and the third connection hole of the another of the two uneven members is configured to allow the fourth connection rod to run through;
two second elastic members, wherein one end of one of the two second elastic members is in contact with the flat surface of one of the two uneven members and is configured to allow the first connection rod to run through; and one end of another of the two second elastic members is in contact with the flat surface of another of the two uneven members and is configured to allow the fourth connection rod to run through; and
a second stopper, wherein the second stopper is disposed on a side, away from the synchronization assembly, of the two second elastic members and fixedly connected to the connection wrap member; and one end of the second stopper is in contact with another end of the one of the two second elastic members, and another end of the second stopper is in contact with another end of the another of the two second elastic members.

14. The support device according to claim 13, wherein
each of the first connection rod and the second connection rod has at least one flat structure in cross-section; each of the first connection hole and the third connection hole is a flat connection hole matching the at least one flat structure; and each of the two friction members and the two uneven members is capable of rotating in sync with the first connection rod and the fourth connection rod; and
the first connection rod and the fourth connection rod are rotatable within the second connection holes, and the uneven wheel connection structure is not in sync with rotations of the first connection rod and the fourth connection rod.

15. The support device according to claim 13, wherein the second elastic member is a square spring, the square spring being a spring having a square cross-section.

16. The support device according to claim 1, wherein the flip assembly comprises: two first flip plates, two fixing members, one connection wrap member, two slide members, two first elastic members, and two second flip plates.

17. A foldable display device, comprising: a flexible display module and a support device;
wherein the support device is disposed on a non-display surface of the flexible display module and connected to the flexible display module to support the flexible display module, the flexible display module comprising a bendable portion and a first unbendable portion and a second unbendable portion disposed on two sides of the bendable portion; and
the support device comprises:
a first support plate, configured to support the first unbendable portion;
a second support plate, configured to support the second unbendable portion; and
a hinge, configured to allow the bendable portion to be folded or unfolded;
wherein the hinge at least comprises a flip assembly, the flip assembly comprising:
a first flip plate, fixedly connected to the first support plate;
a fixing member, rotatably connected to the first flip plate;
a connection wrap member, wrapping the fixing member and fixedly connected to the fixing member;
a slide member, wrapped by the connection wrap member and slidably connected to the fixing member;
a first elastic member, disposed between the fixing member and the slide member, wherein one end of the first elastic member is connected to the fixing member and another end of the first elastic member is connected to the slide member; and
a second flip plate, fixedly connected to the second support plate and rotatably connected to the slide member;
wherein the first elastic member is in a compressed state, and a first compression amount of the first elastic member in a case where the support device is not connected to the flexible display module is less than a second compression amount of the first elastic member in a case where the support device is connected to the flexible display module.

18. The foldable display device according to claim 17, wherein
in the case that the support device is not connected to the flexible display module, the slide member is in abutment against an inner wall of the connection wrap member under an elastic force of the first elastic member; or
in the case that the support device is connected to the flexible display module, a gap is present between the slide member and an inner wall of the connection wrap member.

19. The foldable display device according to claim 17, wherein
in the case that the support device is not connected to the flexible display module and the support device is in an unfolded state, a first gap is present between the first flip plate and the second flip plate; or
in the case that the support device is connected to the flexible display module and the support device is in an unfolded state, a second gap is present between the first flip plate and the second flip plate;
wherein the first gap is greater than the second gap, and a difference value between the first gap and the second gap is a length compensation value for the flexible display module.

20. The foldable display device according to claim 17, wherein
a first curved rotation groove is defined in the fixing member, and the first flip plate comprises a first flip structure, wherein the first flip structure is disposed in the first curved rotation groove and is flippable in the first curved rotation groove; and
a second curved rotation groove is defined in the slide member and the second flip plate has a second flip structure, wherein the second flip structure is disposed in the second curved rotation groove and is flippable in the second curved rotation groove.
